(19) United States
(12) Patent Application Publication
(10) Pub. No.: US 2008/0166893 A1
(43) Pub. Date: Jul. 10, 2008

(54) LOW TEMPERATURE OXIDE FORMATION

(76) Inventors: Jeong Soo Byun, Cupertino, CA (US); Krishnaswamy Ramkumar, San Jose, CA (US)

Correspondence Address: Evan Law Group, LLC, 600 West Jackson Blvd., Suite 625, Chicago, IL, 60661, US

(21) Appl. No.: 11/969,125

(22) Filed: Jan. 3, 2008

Related U.S. Application Data
(60) Provisional application No. 60/883,862, filed on Jan. 8, 2007.

(51) Int. Cl. H01L 21/321

(52) U.S. Cl. 438/798; 257/E21.301

(57) ABSTRACT

A method of forming a semiconductor structure includes oxidizing a gate stack at a temperature of at most 600° C. with a plasma prepared from a gas mixture. The gas mixture includes an oxygen-containing gas and ammonia, and the gate stack is on a semiconductor substrate. The gate stack contains a gate layer, a conductive layer on the gate layer, a metal layer on the conductive layer, and a capping layer on the metal layer.

### CROSS-REFERENCE TO RELATED APPLICATION

This application claims priority to provisional application No. 60/883,862 entitled “Low Temperature Oxide Formation” filed 8 Jan. 2007, attorney docket no. CYP01-110-PRO, the entire contents of which are hereby incorporated by reference, except where inconsistent with the present application.

### BACKGROUND

A semiconductor device typically includes a metal oxide semiconductor (MOS) transistor, which includes a gate stack. FIG. 1 illustrates a conventional gate stack including a gate electrode 110′, where the gate stack is on a semiconductor substrate 101. As shown in FIG. 1, the gate electrode 110′ is on a gate insulator 102, which is on the semiconductor substrate 101. A capping layer 121, typically containing silicon nitride, is on the gate electrode 110′. Also illustrated in FIG. 1, the gate electrode 110′ includes a metal layer 115′ (typically containing tungsten), on a refractory layer 114 (typically containing tungsten nitride), which is on a diffusion barrier layer 117 (typically containing titanium nitride). The diffusion barrier layer 117 is on a conductive layer 116 (typically containing titanium silicide), which is on a gate layer 112′ (typically containing polycrystalline silicon(poly)).

A conventional MOS transistor 210 containing the conventional gate stack is illustrated in FIG. 2. As shown, the transistor includes gate spacers 208 on either side of the gate stack. The transistor also includes source/drain regions 221 and 222, as well as isolation regions 201 in the substrate. During processing, the gate electrode 110′ may loose nitrogen from the refractory layer 114, so that when the refractory layer contains tungsten nitride and the metal layer 115′ contains tungsten, the refractory layer will merge into the metal layer 115′. The conventional MOS transistor and gate stack is described, for example, in U.S. Pat. No. 6,902,993 to Blosse et al. issued 7 Jun. 2005.

As part of processing the gate stack to form the conventional MOS transistor, the gate layer 112′ of the gate electrode 200 is selectively oxidized, to form sidewall oxide 170, as illustrated in FIG. 3, where the portions of the gate electrode above the gate layer are collectively labeled 120. A sidewall oxide having a thickness of 50-70 angstroms is formed, for example, by exposing the gate stack to a mixture of hydrogen and oxygen (10% steam) at a temperature of 750° C. to selectively oxidize the poly relative to the tungsten and tungsten nitride. This selective oxidation of a gate stack is described in U.S. patent application Ser. No. 10/313,048 to Blosse et al. entitled “SELECTIVE OXIDATION OF GATE STACK” filed 6 Dec. 2002.

During selective oxidation of the gate layer, whisker defects may form which contain silicon and titanium. These whisker defects may interfere with device operation, reducing device performance and/or device yield. It is believed that the whisker defects are formed by the reaction of oxygen (O₂) with titanium silicide and silicon at the interface of the gate layer and the conductive layer, due to catalysis by impurities present on the sidewall of the gate stack. The whisker defects may be removed by etching in an asher. It would be desirable to eliminate the formation of the whisker defects, so that they would not need to be removed.

### SUMMARY

In a first aspect, the present invention is a method of forming a semiconductor structure, comprising oxidizing a gate stack at a temperature of at most 600° C. with a plasma prepared from a gas mixture. The gas mixture comprises an oxygen-containing gas and ammonia, and the gate stack is on a semiconductor substrate. The gate stack comprises a gate layer, a conductive layer on the gate layer, a metal layer on the conductive layer, and a capping layer, on the metal layer.

In a second aspect, the present invention is a method of oxidizing silicon, comprising oxidizing the silicon at a temperature of at most 600° C. with a plasma prepared from a gas mixture. The gas mixture comprises an oxygen-containing gas and ammonia.

### BRIEF DESCRIPTION OF THE DRAWINGS

FIG. 1 shows a conventional gate stack including a gate electrode.

FIG. 2 shows a conventional MOS transistor.

FIG. 3 shows a gate electrode having sidewall oxide.

### DETAILED DESCRIPTION

The present invention makes use of the discovery of a method of selective oxidation of silicon, without forming whisker defects. The selective oxidation is carried out in a plasma, prepared from a gas mixture containing ammonia, an oxygen-containing gas, and optionally an inert gas. The oxidation takes place at a temperature of at most 600° C. Preferably, the plasma is prepared using both high frequency and low frequency RF energy. The selective oxidation forms sidewall oxide on the poly of the gate layer without oxidizing the metal layer, and without the formation of whisker defects.

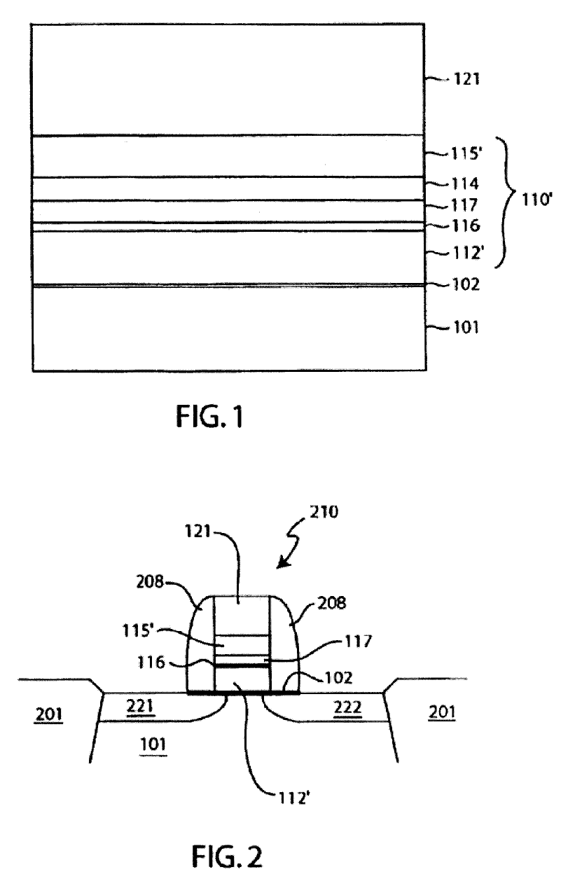

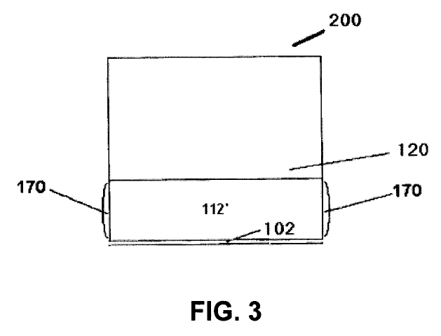

The gate stacks may be formed by conventional methods, for example as described in U.S. Pat. No. 6,680,516 to Blosse et al. issued 20 Jan. 2004 and U.S. Pat. No. 6,902,993 to Blosse et al. issued 7 Jun. 2005. FIG. 1 illustrates a gate stack including a gate electrode 110′, where the gate stack is on a semiconductor substrate 101. As shown in FIG. 1, the gate electrode 110′ is on a gate insulator 102, which on the semiconductor substrate 101. A capping layer 121 is on the gate electrode 110′. Also illustrated in FIG. 1, the gate electrode 110′ includes a metal layer 115′, on a refractory layer 114, which is itself on a diffusion barrier layer 117. The diffusion barrier layer 117 is on a conductive layer 116, which is on a gate layer 112′.

The gate layer may contain a variety of semiconductor materials. Typically, the gate layer contains poly or amorphous silicon. The gate layer may be doped with one type of dopant (P⁺ or N⁺), or it may contain both types of dopants in discrete regions. A split gate is a gate layer containing both P⁺ and N⁺ doping regions.

In the case of a split gate, those regions of the gate layer that are P⁺ doped (such as with B or BF²⁺) are over N⁻ doped channel regions of the substrate, forming a PMOS device; those regions of the gate layer that are N⁺ doped (such as with As⁺ or phosphorus⁺) are over P⁻ doped channel regions of the substrate, forming an NMOS device. The P⁺ and N⁺ doping regions of the gate layer are separated by a region which is on an isolation region of the substrate. The doping of the regions of the gate layer is preferably carried out after forming the gate layer, by masking and doping each region separately, or by an overall doping of the gate layer with one dopant type, and then masking and doping only one region with the other dopant type (counter doping).

The conductive layer preferably contains titanium, tantalum, zirconium, hafnium, cobalt, and mixture, alloys or compounds thereof, including titanium silicide. The conductive layer preferably has a thickness of 35-65 angstroms, more preferably 45-60 angstroms, based on the thickness of the layer as formed, before reaction with other layers. For example, if the conductive layer contains titanium silicide, it may be formed by forming a layer of titanium having a thickness of 35-65 angstroms prior to reaction with the gate layer to form titanium silicide.

The diffusion barrier layer on the conductive layer is optional. Preferably, the diffusion barrier layer contains titanium, tantalum, zirconium, hafnium, cobalt, and mixture, alloys or compounds thereof, including titanium nitride. This layer may be formed by reaction of nitrogen from the layer above, or by the reaction of ammonia with part of the material applied to form the conductive layer.

The refractory layer on the conductive layer, or on the diffusion barrier layer, is also optional. Preferably, the refractory layer contains a nitride, such as titanium nitride or tungsten nitride. The thickness of the refractory layer, as applied, is preferably 25-75 angstroms.

The metal layer preferably contains a highly conductive metal such as tungsten. Preferably, the metal layer has a thickness of 300-500 angstroms, more preferably 350-450 angstroms, including 375-400 angstroms.

Thermal treatment of the gate electrode may be performed before forming the capping layer. Such a thermal treatment may result in some reaction of the layers of the gate electrode. For example, thermal treatment may cause reaction of the gate layer with the conductive layer to form silicide in the conductive layer, and/or the metal layer may pick up some nitrogen. The capping layer, which protects and electrically insulates the gate electrode, is preferably formed after the thermal treatment. The capping layer preferably is an insulator, such as a layer containing silicon nitride.

The capping layer may be patterned and used as a hard mask for etching the gate electrode. The gate electrode layers may be subjected to one or more etching treatments to pattern the entire gate electrode. The gate insulator may be etched along with the gate electrode, or it may be patterned in a separate step.

A sidewall oxide is then formed on the gate stack by selective oxidation. The selective oxidation is carried out in a plasma, prepared from a gas mixture containing ammonia, an oxygen-containing gas, and optionally an inert gas. The oxidation takes place at a temperature of at most 600° C. Preferably, the plasma is prepared using both high frequency and low frequency RF energy. The selective oxidation forms sidewall oxide on the poly of the gate layer without oxidizing the metal layer, and without the formation of whisker defects.

The gas mixture from which the plasma is formed contains ammonia (NH₃) and an oxygen-containing gas. Preferably, the oxygen-containing gas is nitrous oxide (N₂O), dioxygen (O₂), ozone (O₃), or mixtures thereof. Preferably, an inert gas, such as nitrogen (N₂), argon, helium, neon, or mixtures thereof, is also present in the gas mixture. The ratio of flow rates of the oxygen-containing gas:ammonia is preferably 1:20 to 10:1, more preferably 1:10 to 1:1, most preferably 1:5 to 1:2, including 1:4. The flow rate of the oxygen-containing gas is preferably 100-2000 sccm, including 200, 500 and 1000 sccm. The flow rate of ammonia gas is preferably 100-10000 sccm, including 200, 500, 1000, and 2000 sccm.

The plasma is preferably prepared using both high frequency and low frequency RF radiation. As used in the present application, high frequency is at least 4 MHz, and low frequency is less than 4 MHz. Preferably, high frequency is 5-15 MHz, including 13.56 MHz. Preferably, low frequency is 100-1000 KHz, including 450 KHz. Preferably, the high frequency power is at least 100 watts, more preferably 0.1-1 kW, such as 0.2-0.8 kW, including 0.3 kW. Preferably, the low frequency power is at least 10 watts, more preferably 0.01-1 kW, such as 0.03-0.5 kW, including 0.05 kW. Preferably, the total power used is 0.1-1 kW. Preferably, the oxidation is carried out for 5 seconds to 5 minutes, including 30 seconds.

The oxidation is carried out at a temperature of at most 600° C., preferably at a temperature of 250-450° C. Preferably, the oxidation is carried out in a plasma enhanced chemical vapor deposition (PECVD) tool that can produce a plasma using both high and low frequency RF radiation, such as a NOVELLUS CONCEPT system (Novellus Systems, Inc., San Jose, Calif.). The thickness of the oxide produced may be, for example, 20-50 angstroms thick. The selective oxidation of the present invention may also be used to form oxide on silicon or polysilicon, without oxidizing metal, such as tungsten, that may be present on a structure.

Other processing may be used to complete formation of semiconductor devices from the semiconductor structure. For example, source/drain regions may be formed in the substrate, spacers may be formed on the sides of the gate stack, additional dielectric layers may be formed on the substrate, and other contacts and metallization layers may be formed on these structures. These additional elements may be formed before, during, or after the method of the present invention.

The related processing steps, including the etching of the gate stack layers and other steps such as polishing, cleaning, and deposition steps, for use in the present invention are well known to those of ordinary skill in the art, and are also described in Encyclopedia of Chemical Technology, Kirk-Othmer, Volume 14, pp. 677-709 (1995); Semiconductor Device Fundamentals, Robert F. Pierret, Addison-Wesley, 1996; Wolf, Silicon Processing for the VLSI Era, Lattice Press, 1986, 1990, 1995, 2002 (vols 1-4, respectively); Microchip Fabrication 5th. edition, Peter Van Zant, McGraw-Hill, 2004; U.S. Pat. No. 6,803,321 to Blosse et al. issued 12 Oct. 2004; U.S. Pat. No. 6,774,012 to Sundar Narayanan issued 10 Aug. 2004; and U.S. Pat. No. 6,902,993 to Blosse et al. issued 7 Jun. 2005.

The semiconductor structures of the present invention may be incorporated into a semiconductor device such as an integrated circuit, for example a memory cell such as an SRAM, a DRAM, an EPROM, an EEPROM etc.; a programmable logic device; a data communications device; a clock generation device; etc. Furthermore, any of these semiconductor devices may be incorporated in an electronic device, for example a computer, mobile phone, an airplane or an automobile.

What is claimed is:

1. A method of forming a semiconductor structure, comprising:
oxidizing a gate stack at a temperature of at most 600° C. with a plasma prepared from a gas mixture;
wherein the gas mixture comprises an oxygen-containing gas and ammonia,
the gate stack is on a semiconductor substrate, and
the gate stack comprises:
a gate layer,
a conductive layer, on the gate layer,
a metal layer, on the conductive layer, and
a capping layer, on the metal layer.

2. The method of claim 1, wherein
the oxidizing of the gate stack is at a temperature of 250-450° C.,
the plasma is prepared with high frequency and low frequency RF radiation,
the gate layer comprises silicon,
the conductive layer comprises titanium,
the metal layer comprises tungsten, and
the capping layer comprises silicon nitride.

3. The method of claim 2, wherein the oxygen-containing gas comprises at least one member selected from the group consisting of nitrous oxide, dioxygen, ozone, and mixtures thereof.

4. The method of claim 2, wherein the oxygen-containing gas comprises nitrous oxide.

5. The method of claim 2, wherein the high frequency RF radiation has a frequency of 5-15 MHz.

6. The method of claim 2, wherein the low frequency RF radiation has a frequency of 100-1000 KHz.

7. The method of claim 2, wherein the high frequency RF radiation has a power of 0.2-0.8 kW.

8. The method of claim 2, wherein the low frequency RF radiation has a power of 0.03-0.5 kW.

9. The method of claim 2, wherein the gate stack further comprises at least one additional layer selected from the group consisting of:
a diffusion barrier layer comprising titanium, on the conductive layer, and a refractory layer comprising tungsten, on the conductive layer.

10. The method of claim 2, wherein a ratio of flow rates of the oxygen-containing gas:ammonia is 1:10 to 1:1.

11. The method of claim 10, wherein
the oxygen-containing gas comprises nitrous oxide,
the high frequency RF radiation has a frequency of 5-15 MHz,
the low frequency RF radiation has a frequency of 100-1000 KHz,
the high frequency RF radiation has a power of 0.2-0.8 kW, and
the low frequency RF radiation has a power of 0.03-0.5 kW.

12. A method of making a semiconductor device, comprising:
forming a semiconductor structure by the method of claim 2, and
forming a semiconductor device from the semiconductor structure.

13. A method of making an electronic device, comprising:
forming a semiconductor device by the method of claim 12, and
forming an electronic device comprising the semiconductor device.

14. A method of oxidizing silicon, comprising:
oxidizing the silicon at a temperature of at most 600° C. with a plasma prepared from a gas mixture;
wherein the gas mixture comprises an oxygen-containing gas and ammonia.

15. The method of claim 14, wherein the silicon is present in a structure comprising metal.

16. The method of claim 15, wherein the metal comprises tungsten, and the tungsten is not oxidized during the oxidizing of the silicon.

17. The method of claim 16, wherein
the oxidizing is at a temperature of 250-450° C., and
the plasma is prepared with high frequency and low frequency RF radiation.

18. The method of claim 17, wherein
a ratio of flow rates of the oxygen-containing gas:ammonia is 1:10 to 1:1.
the oxygen-containing gas comprises nitrous oxide,
the high frequency RF radiation has a frequency of 5-15 MHz,
the low frequency RF radiation has a frequency of 100-1000 KHz,
the high frequency RF radiation has a power of 0.2-0.8 kW, and
the low frequency RF radiation has a power of 0.03-0.5 kW.

19. In a method of forming sidewall oxide on a gate stack by oxidizing with steam, the improvement comprising replacing the steam with a plasma prepared from a gas mixture including an oxygen-containing gas and ammonia, prepared with high frequency and low frequency RF radiation.

20. The method of claim 19, wherein the gate stack contains (i) a gate layer containing silicon, (ii) a conductive layer containing titanium, on the gate layer, (iii) a metal layer containing tungsten, on the conductive layer, and (iv) a capping layer containing silicon nitride, on the metal layer, and the oxygen-containing gas comprises nitrous oxide.
